(19) United States
(12) Patent Application Publication
(10) Pub. No.: US 2010/0133957 A1
(43) Pub. Date: Jun. 3, 2010

(54) PIEZO ACTUATOR WITH INCREASED DISPLACEMENT CAPACITY

(75) Inventors: Carsten Schuh, Baldham (DE); Thorsten Steinkopff, Egmating (DE); Andreas Wolff, Munchen (DE)

Correspondence Address: YOUNG & THOMPSON, 209 Madison Street, Suite 500, Alexandria, VA, 22314, US

(73) Assignee: SIEMENS AKTIENGESELLSCHAFT, München (DE)

(21) Appl. No.: 11/993,465

(22) PCT Filed: Jun. 12, 2006
(86) PCT No.: PCT/EP2006/063081

§ 371 Date: Feb. 13, 2008

(30) Foreign Application Priority Data
Jun. 22, 2005 (DE) 10 2005 028 976.2

(51) Int. Cl. H01L 41/083

(52) U.S. Cl. 310/330

(57) ABSTRACT

The invention relates to a high-lifting capacity piezoelectric actuator (1) comprising an piezoelectric layer (10) and a second layer (20) whose material gradient is directed to the thickness. An electric field produces different extension degrees in said piezoelectric layer (10) and in the second layer (30), thereby increasing the lifting capacity of the piezoelectric actuator (1) in combination with an impressed mechanical prestressing. The inventive piezoelectric actuator is used at a low voltage, for example, for bio and medical engineering (micropumps, microvalves), in industrial electronic engineering (pneumatic valves) and for microactuators and micromotors.

The present invention relates to piezo actuators which, when a voltage is applied, exhibit a particular extension behavior as a function of said voltage.

Piezo actuators are used in a wide variety of technical fields. They are produced, for example, in multilayer designs. These multilayer piezo actuators are used for controlling injection valves in internal combustion engines, for controlling positioning tables or in precision mechanics, to mention just a few examples.

U.S. Pat. No. 6,274,967 discloses a multilayer piezoelectric actuator equipped with a pretensioning mechanism for introducing force into the piezoelectric layers. With the aid of the pretensioning mechanism, single-axis compressive stress is applied to the piezoelectric layers along the stack direction of the piezo actuator.

WO 2004/015789 A2 discloses a piezo actuator comprising at least one stacked piezo element. The piezo element, which is enclosed by electrodes, is held in a pretensioning device in such a way that force is introduced to a sub-volume of the piezoelectric layer. The mechanical pretension applied to the piezoelectric layer in combination with an electric field acting in the piezoelectric layer produces an increased extension of the piezo actuator compared to conventional piezo actuator designs. In spite of this extension behavior, i.e. displacement capacity, of the piezo actuator, various fields of technology such as micromechanics require a further displacement amplification or rather an improved extension behavior of the piezo actuator.

The object to be achieved by the present invention is therefore to provide a piezo actuator with enhanced displacement behavior compared to the prior art.

The present invention discloses a piezo actuator having the following features: at least one piezoelectric layer which is disposed between two opposed electrode layers for the purpose of generating an electric field in the piezoelectric layer, at least one second layer which is disposed adjacent to the piezoelectric layer in order to interact therewith, and a preloading mechanism by means of which the piezoelectric layer and the second layer can be stressed in such a way that, when an electric field is generated in the piezoelectric layer, the stress present in the two layers assists an extension behavior of the piezo actuator.

The present invention is based on the principle of combining a piezoelectric layer producing a piezo effect of a particular magnitude with a second layer which is characterized by a lesser piezo effect compared to the piezoelectric layer. A lesser piezo effect in this context means that, in the second layer, piezoelectrically, ferroelectrically and/or ferroelastically produced extensions are less pronounced than in the piezoelectric layer subject to the same electric field strength or mechanical loading. Because of the combination of these two layers with different material properties, the applied stresses increase the displacement capacity of the piezo actuator compared to the prior art.

The second layer of the piezo actuator has a different electrical conductivity and/or electrical permittivity and/or piezoelectric coefficient and/or modulus of elasticity from that of the piezoelectric layer.

By providing the second layer with different material properties compared to the piezoelectric layer, the piezo effect is partially restricted or inhibited in the piezoelectric layer, which combined with the applied stresses results in an improvement in the extension behavior of the piezo actuator.

According to another preferred embodiment, the piezoelectric layer and the second layer are constituted by a gradient layer having a piezoelectric region and a region of varying material properties, i.e. a material gradient, in the direction perpendicular to the electrode layers.

Said gradient layer is characterized e.g. in the direction perpendicular to the electrode layers by a diminishing piezo effect, by a varying electrical conductivity and/or modulus of elasticity. With the aid of this gradient layer, influencing of the piezoelectrically active region—the piezoelectric layer—by a piezoelectrically less active region—the second layer—is achieved, which results in an improved piezo actuator displacement capacity compared to the prior art.

The present invention and preferred embodiments thereof will now be explained in greater detail with reference to the following drawings, detailed description and appended claims:

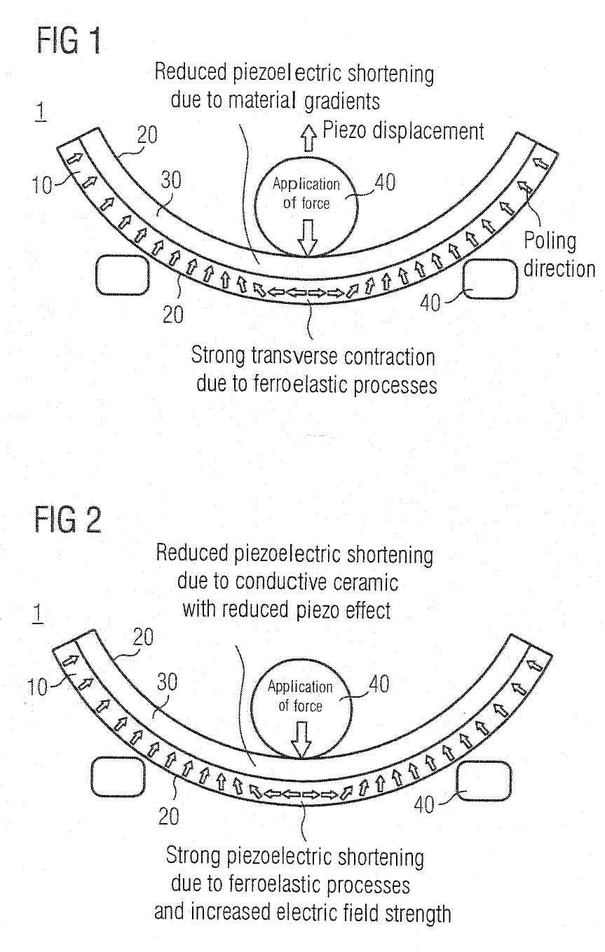

FIGS. 1 to 3 show preferred material configurations and their effects in the present piezo actuator.

The preferred piezo actuator 1, which is schematically illustrated in FIG. 1, comprises a piezoelectric layer 10, a second layer 30 and electrode layers 20. The electrode layers 20 are disposed opposite one another, thereby enclosing the piezoelectric layer 10 and the second layer 30. It is likewise conceivable for the electrode layers 20 to be disposed in such a way that they only enclose the piezoelectric layer 10. In addition to the layers 10, 20, 30, the piezo actuator 1 incorporates a preloading mechanism 40. Said preloading mechanism 40 introduces a mechanical bending stress into the layer structure 10, 20, 30.

The second layer 30 has different material properties from those of the piezoelectric layer 10. The differences compared to the piezoelectric layer 10 can be, for example, a different electrical conductivity and/or electrical permittivity and/or piezoelectric coefficient and/or modulus of elasticity from that of the piezoelectric layer 10. It is likewise conceivable for a variation in the material properties in the second layer 30 to be achieved with the aid of a material gradient. This material gradient characterizes a region of varying material properties, the material properties preferably varying in the sheet plane perpendicular to the electrode layers 20.

According to a preferred embodiment, the piezoelectric layer 10 and the second layer 30 are not implemented as separate layers. The two layers 10, 30 form a common gradient layer which, viewed in the sheet plane of the figures, have a piezoelectric region and a region of varying material properties in the direction perpendicular to the electrode layers 20. By implementing the piezoelectric layer 10 and the second layer 30 in a common gradient layer, e.g. interfacing problems between two separate layers lying one on top of the other are eliminated. In addition, the production costs are reduced since only one gradient layer is produced instead of two individual layers. At the same time, in addition to the above-mentioned effects it is possible to implement all the required material properties which could also be produced using two separate layers 10, 20.

Within said gradient layer consisting of the piezoelectric layer 10 and the second layer 30, there can be provided, viewed in the thickness direction, i.e. perpendicular to the electrode layers 20, a piezoelectric sub-region followed by a region of varying electrical conductivity and/or varying dielectric permittivity and/or varying piezoelectric coefficient and/or varying modulus of elasticity. When a voltage is applied to the piezoelectric layer 10 or to the piezoceramic sub-region, this special material configuration of the layers 10, 30 produces within the gradient layer additional piezo- and ferroelectric extension components. According to the external mechanical clamping/preloading conditions produced by the preloading mechanism 40, under equilibrium conditions a different deformation is present than if only a single piezoelectric layer 10 were present. Because of the strongly nonlinear relationship between extension state and magnitude of the layer curvature, for each layer 10, 30 a significantly larger displacement change of the piezo actuator 1 can be achieved than is possible with the piezoceramic layer thickness change utilized in conventional stack actuators. With the aid of the additionally introduced material gradient within the gradient layer, the displacement of the piezo actuator 1 is increased still further.

When the above-described layer structure 10, 30 has been created, the piezoelectric layer 10 or the piezoelectric sub-region in the gradient layer is poled by applying a voltage to the electrode layers 20. The voltage applied and the electric field thereby generated in the piezoelectric layer 10 aligns the ferroelectric domains in field direction, which is schematically indicated by arrows standing perpendicular to the electrode layers 20.

When poling is complete, the layer structure 10, 20, 30 is disposed in the preloading mechanism 40. The latter introduces mechanical stresses into the layer structure 10, 20, 30. A 3-point bending arrangement 40 is shown by way of example, but other preloading mechanisms are also conceivable, such as a 4-point bending arrangement. By means of the mechanical stresses introduced into the layer structure 10, 20, 30, the preloading mechanism produces a sub-region in the piezoelectric layer 10 which is loaded by tensile stresses in the sheet plane of the drawings lying parallel to the electrode layers 20. In the examples shown in FIGS. 1 to 3, this sub-region loaded by tensile stresses is located in the vicinity of the apex of the bent layer structure 10, 20, 30. The arrows oriented parallel to the electrode layers 20 near the apex indicate that the tensile stresses introduced produce ferroelastic domain wall shifts and extension changes in the layer structure 10, 20, 30 in this region.

If an electric field is now generated in the piezoelectric layer 10, this results in domain wall shifts, i.e. in the arrows shown for illustrative purposes in the figures being oriented perpendicular to the electrode layers 20. The electric field produces within the piezoelectric layer 10 a transverse contraction, i.e. a shortening of the piezoelectric layer 10 viewed in the direction parallel to the electrode layers 20 within the sheet plane. Within the second layer 30 or, if the above-described gradient layer is present, within the piezoelectrically less active region, a less pronounced transverse contraction or shortening takes place compared to the piezoelectric layer 10. Due to the more pronounced shortening in the piezoelectric layer 10 compared to the graduated material layer, a displacement amplification of the piezo actuator 1 caused by producing a deflection by introducing an external force is additionally increased by means of different material properties compared to the piezoelectric layer 10. The advantage of the piezo actuator 1 therefore lies in the selective combination of the piezoelectric, ferroelectric and ferroelastic effects in order to produce piezo actuators with a much greater displacement compared to conventional stack actuators. Through the combination of piezoceramic multilayer technology, micropatterning and micromechanics, new inexpensive mass applications for low-voltage operation, e.g. in the field of biotechnology and medical engineering (micro pumps, micro valves), industrial electronics (pneumatic valves) and micro actuators and micro motors can be implemented using the above-described method and device.

FIG. 2 shows by way of example a layer structure 10, 20, 30 having a conductive ceramic with reduced piezo effect as the second layer 30. If the preloaded layer structure 10, 20, 30 is subjected to an electric field, in the second layer 30 there is initially a slight transverse contraction or shortening at the apex of the schematically illustrated bend compared to the piezoelectric layer 10. In addition, the conductivity of the second layer 30 results in an intensification of the electric field present in the piezoelectric layer 10. Because of the increased piezo effect, the more intense electric field results in a greater extension in the direction perpendicular to the electrode layers 20 within the piezoelectric layer 10. These extension states within the layer structure 10, 20, 30 interact with the applied mechanical preloads to produce an increased displacement capacity of the piezo actuator 1.

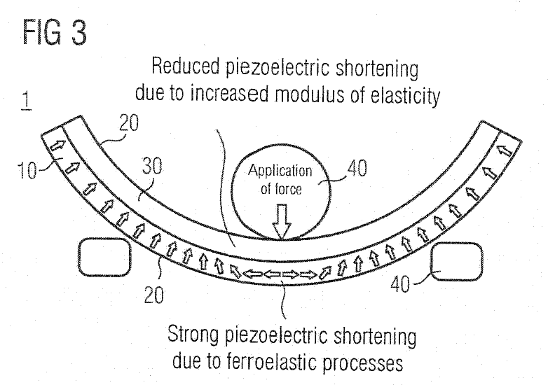

FIG. 3. shows a layer structure 10, 20, 30, the second layer 30 of which is characterized by an increased modulus of elasticity compared to the piezoelectric layer 10. In spite of piezoelectric material properties within the second layer 30, the increased modulus of elasticity results in a reduced shortening in the vicinity of the apex of the layer structure 10, 20, 30 compared to the shortening in this region within the piezoelectric layer 10. Therefore, also in the layer structure 10, 20, 30 shown by way of example in FIG. 3, different extension states are produced in the layers 10 and 30 which in combination with the applied preloading result in an increased displacement of the piezo actuator 1.

1. A piezo actuator (1) incorporating the following features:
a. at least one piezoelectric layer (10) which is disposed between two opposed electrode layers (20) for the purpose of generating an electric field in the piezoelectric layer (10),
b. at least one second layer (30) which is disposed adjacent to the piezoelectric layer (10) in order to interact with same, and
c. a preloading mechanism (40) by means of which the piezoelectric layer (10) and the second layer (20) can be stressed so that, when an electric field is generated in the piezoelectric layer (10), the stress present in the two layers (10, 30) assists an extension behavior of the piezo actuator (1).

2. The piezo actuator (1) as claimed in claim 1, the second layer (30) of which exhibits a smaller piezoelectric extension, in particular a piezoelectric extension parallel and/or perpendicular to the electric field, compared to the piezoelectric layer (10) when subjected to an electric field of the same strength.

3. The piezo actuator as claimed in claim 1, the second layer of which (30) exhibits a different electrical conductivity and/or dielectric permittivity and/or piezoelectric coefficient and/or modulus of elasticity from that of the piezoelectric layer (10).

4. The piezo actuator as claimed in claim 1, the second layer (30) of which is disposed on one of the electrode layers (20) or directly on the piezoelectric layer (10).

5. The piezo actuator (1) as claimed in claim 1, the second layer (30) of which has a material gradient which characterizes a region of varying material properties.

6. The piezo actuator as claimed in claim 1, the piezoelectric layer (10) and second layer (30) of which are combined in a gradient layer having a piezoelectric region and a region of varying material properties in the direction perpendicular to the electrode layers (20).

7. The piezo actuator as claimed in claim 6, the gradient layer of which contains a region of varying electrical conductivity and/or dielectric permittivity and/or piezoelectric coefficient and/or modulus of elasticity.

8. The piezo actuator (1) as claimed in claim 1, having a preloading mechanism (40) with which a bend can be introduced into the piezoelectric layer (10) and the second layer (30) so that, in sub-regions, the piezoelectric layer (10) can be loaded by tensile stresses parallel to the electrode layers (20), preferably at the apex of the bend.

9. The piezo actuator as claimed in claim 2, the second layer of which (30) exhibits a different electrical conductivity and/or dielectric permittivity and/or piezoelectric coefficient and/or modulus of elasticity from that of the piezoelectric layer (10).

10. The piezo actuator as claimed in claim 2, the second layer (30) of which is disposed on one of the electrode layers (20) or directly on the piezoelectric layer (10).

11. The piezo actuator (1) as claimed in claim 2, the second layer (30) of which has a material gradient which characterizes a region of varying material properties.

12. The piezo actuator as claimed in claim 2, the piezoelectric layer (10) and second layer (30) of which are combined in a gradient layer having a piezoelectric region and a region of varying material properties in the direction perpendicular to the electrode layers (20).

13. The piezo actuator (1) as claimed in claim 2, having a preloading mechanism (40) with which a bend can be introduced into the piezoelectric layer (10) and the second layer (30) so that, in sub-regions, the piezoelectric layer (10) can be loaded by tensile stresses parallel to the electrode layers (20), preferably at the apex of the bend.
